(19) United States
(12) Patent Application Publication
(10) Pub. No.: US 2026/0269574 A1
(43) Pub. Date: Sep. 10, 2026

(54) STACKING LASER-BANKS WITH HOLES FOR OBTAINING A HIGH BRIGHTNESS WHITE LIGHT SOURCE

(71) Applicant: SIGNIFY HOLDING B.V., EINDHOVEN (NL)

(72) Inventors: TIES VAN BOMMEL, HORST (NL); RIFAT ATA MUSTAFA HIKMET, EINDHOVEN (NL)

(21) Appl. No.: 19/166,520

(22) PCT Filed: Mar. 13, 2024
(86) PCT No.: PCT/EP2024/056724

§ 371 Date: Sep. 18, 2025

(30) Foreign Application Priority Data
Mar. 21, 2023 (EP) 23163306.6

(51) Int. Cl. H01S 5/40; F21V 9/32; F21Y 115/30; H01S 5/024

(52) U.S. Cl. CPC H01S 5/4087; F21V 9/32; H01S 5/02469; H01S 5/4012; F21Y 2115/30

(57) ABSTRACT

The invention provides a light generating system (1000) comprising a first support (2100), a first 2D array (2110) of first light sources (10), first optical elements (410), a second support (2200), a second 2D array (2210) of second light sources (20), and second optical elements (420), wherein: (A) the first support (2100) is configured to support the first light sources (10) and the second support (2200) is configured to support the second light sources (20); the first light sources (10) are configured to generate first light source light (11) and the second light sources (20) are configured to generate second light source light (21); wherein the first light sources (10) comprise laser diodes and the second light sources (20) comprise laser diodes; wherein the first support (2100) comprises a first thermally conductive element (2160) and/or wherein the second support (2200) comprises a second thermally conductive element (2260); (B) the first optical elements (410) are configured downstream of the first light sources (10), and are configured to collimate the first light source light (11) into first beams (15) of collimated first light source light (11); the second optical elements (420) are configured downstream of the second light sources (20), and are configured to collimate the second light source light (21) into second beams (25) of collimated second light source light (21); (C) the first support (2100) and the second support (2200) are configured stacked, wherein the second support (2200) comprises an array (2220) of through-holes (2250) configured aligned with the first optical elements (410) to allow propagation of at least part of the collimated first light source light (11) through the second support (2200); and (D the light generating system (1000) is configured to generate system light (1001) comprising one or more of the first light source light (11) and the second light source light (21).

### FIELD OF THE INVENTION

The invention relates to a light generating system comprising a first and a second support, a first and a second 2D array of first and second light sources, and first and second optical elements. The invention further relates to a lighting device comprising the light generating system.

### BACKGROUND OF THE INVENTION

Light generating systems comprising optics are known in the art. For instance, WO2022073895A1 describes a light generating system comprising a light generating device, a luminescent body, and first optics, wherein: the light generating device is configured to generate device light; wherein the light generating device comprises a laser; the luminescent body comprises a luminescent material, wherein the luminescent material is configured to convert at least part of the device light into luminescent material light, and wherein the luminescent body is transmissive for at least part of the luminescent material light; the first optics are transmissive for at least part of the device light and reflective for at least part of the luminescent material light, wherein the first optics comprise a primary optic surface having a first surface area A1, wherein the primary optic surface is configured in a light receiving relationship with the light generating device; the luminescent body is enclosed by a cavity having a cavity opening having a smallest cross-sectional area A2, wherein the cavity is at least partly defined by the optics; wherein the first optics comprises the cavity opening; wherein A2<A1 and the cavity being reflective for the luminescent material light and the luminescent material light substantially only exiting the cavity via the cavity opening.

### SUMMARY OF THE INVENTION

Applications such as stage lighting, stadium lighting, transport infrastructure, etc. may require using high intensity white light. Laser lighting may be used for high brightness white lighting applications. Recent developments show that instead of individual lasers, laser-banks may be used in laser lighting. A laser-bank is an array of aligned laser diodes arranged on a carrier of which the laser light is collimated by a lens-plate comprising an array of tiny lenses. It is desired to (further) improve the performance and/or functionality of laser lighting by laser banks. Current applications, may however not allow compact high intensity system.

Hence, it is an aspect of the invention to provide a light generating system, which preferably further at least partly obviates one or more of above-described drawbacks. The present invention may have as object to overcome or ameliorate at least one of the disadvantages of the prior art, or to provide a useful alternative.

According to a first aspect, the invention provides a light generating system. In embodiments, the light generating system may especially comprise a first support, a first 2D array of first light sources, and first optical elements. Further, the light generating system may comprise a second support, a second 2D array of second light sources, and second optical elements. In embodiments, the first support may be configured to support the first light sources. Moreover, the second support may be configured to support the second light sources. The first light sources may especially be configured to generate first light source light. The second light sources may further be configured to generate second light source light. In particular, the first light sources may comprise laser diodes. Further, the second light sources may also comprise laser diodes. The first support may comprise a first thermally conductive element. Additionally or alternatively, the second support may comprises a second thermally conductive element. In embodiments, the first optical elements may be configured downstream of the first light sources. Further, the first optical elements may be configured to collimate the first light source light into first beams of collimated first light source light. Moreover, the second optical elements may be configured downstream of the second light sources. In particular, the second optical elements may be configured to collimate the second light source light into second beams of collimated second light source light. In embodiments, the first support and the second support may be configured stacked. The second support may comprise an array of through-holes, especially an opening array of through-holes. The through-holes may in particular be configured aligned with the first optical elements. Thereby, the through-holes may allow propagation of at least part of the collimated first light source light through the second support. In embodiments, the light generating system may be configured to generate system light. The system light may especially comprise one or more of the first light source light and the second light source light. Therefore, in embodiments, the invention provides a light generating system comprising a first support, a first 2D array of first light sources, first optical elements, a second support, a second 2D array of second light sources, and second optical elements, wherein: the first support is configured to support the first light sources and the second support is configured to support the second light sources; the first light sources are configured to generate first light source light and the second light sources are configured to generate second light source light; wherein the first light sources comprise laser diodes and the second light sources comprise laser diodes; wherein the first support comprises a first thermally conductive element and/or wherein the second support comprises a second thermally conductive element; the first optical elements are configured downstream of the first light sources, and are configured to collimate the first light source light into first beams of collimated first light source light; the second optical elements are configured downstream of the second light sources, and are configured to collimate the second light source light into second beams of collimated second light source light; the first support and the second support are configured stacked, wherein the second support comprises an array of through-holes configured aligned with the first optical elements to allow propagation of at least part of the collimated first light source light through the second support; and the light generating system is configured to generate system light comprising one or more of the first light source light and the second light source light.

With the present invention, a laser-based (or laser-bank-based) system generating high intensity white light may be provided. Especially, the invention may provide a further improvement on the functionality of laser-based (such as laser-bank-based) light generating systems through the use of two (or more) stacked laser arrangements (such as stacked laser-banks). As lasers provide (extremely) collimated light with high intensity, the light generated by a first laser arrangement (such as a laser-bank) may in embodiments pass through the through-holes of a second laser arrangement (such as a laser-bank). The system light may thereby comprise light from both laser arrangements, such as laser-banks. Hence, the system light may in embodiments have improved brightness and/or intensity. In this way, the invention may in embodiments provide stacking laser-banks with holes for obtaining a high brightness white light source for use in e.g., stage-lighting fixtures, stage stadium lighting, or transport infrastructure lighting. The invention is further described in relation to laser banks with laser bars and arrays of (diode) lasers, but may refer to other laser arrangements as well.

As mentioned before, the invention provides amongst others a light generating system comprising in embodiments at least two stacked laser arrangements (or “laser array arrangements”). The first laser arrangement may especially comprise a first support, a first 2D array of first light sources, and first optical elements. The second laser arrangement may in embodiments comprise a second support, a second 2D array of second light sources, and second optical elements. Here below, embodiments of these elements are described in more detail.

In embodiments, the light generating system may comprise a first support and a second support. In embodiments, a support may comprise a material with high thermal conductivity. Laser bars may be directly placed on such a support with high thermal conductivity or canned lasers may be placed in openings in a support with high thermal conductivity. A support may in embodiments comprise one or more structural elements, especially a board. In certain embodiments, a support may comprise a printed circuit board (“PCB”). Yet, in embodiments, a support may comprise a main support and a further structural element, such as a PCB, which may be functionally coupled to the main support. A support may in embodiments comprise a metal such as aluminum and/or copper and their alloys.

Especially, a support may be a structure upon which other elements may be coupled to or configured on. Especially, a support may be configured to support light sources. Furthermore, in embodiments, the light generating system may comprise one or more light sources functionally coupled to the support. Hence, a support may especially have features to accommodate the aforementioned light sources. For instance, a support may comprise ports to connect to the light sources. Especially, the light sources may comprise electrodes or nodes which may be functionally coupled to the support. Here, functionally coupled may refer to securing the light sources to the support such that the electrical components are secured in place with substantially no relative motion between the support and the light sources. In embodiments, the light sources may be electrically coupled to the support. That is, the light sources may especially be connected to (other) electrical components via the support. Hence, alternatively or additionally, functionally coupled may refer to electrical contact of the light sources with one or more electrically conductive tracks comprised by the support. Herein, each of the first support and the second support may support a set of light sources. Thereby, the first support may be configured to support the first light sources and the second support may be configured to support the second light sources.

Moreover, a support may comprise elements for thermal management. A support may especially comprise thermally conductive elements for thermal management. The thermally conductive element may transfer heat from a hotter element to a cooler element and/or to air. For that purpose, the thermally conductive element, especially the thermally conductive sheet-like element, may have thermally conductivity. A thermally conductive element may especially have a thermal conductivity of at least about 0.5 W/(m*K), more especially at least about 1 W/(m*K), like at least about 2 W/(m*K), such as at least about 5 W/(m*K), like especially at least about 10 W/(m*K). However, lower thermal conductivities may also be usable to transfer heat away (e.g., from an electrical component). The thermally conductive element may have a thermal conductivity of up to 500 W/(m*K), such as up to 300 W/(m*K). Especially, however, the thermally conductive element may have a thermal conductivity of at least about 100 W/(m*K), such as at least about 200 W/(m*K). Hence, the thermally conductive elements may be effective conductors of heat (away from heat-sensitive or heat-generating elements, e.g., a light source). This may result in improved lifespan/performance of the light generating system. Therefore, the first support may comprise a first thermally conductive element. Additionally or alternatively, the second support may comprise a second thermally conductive element. The first thermally conductive element and the second thermally conductive element may in embodiments be individually selected from the group comprising a heat sink, a heat spreader, and a two-phase cooling device.

Therefore, the thermally conductive element may comprise a heatsink. Heatsinks are known in the art. The term “heatsink” (or heat sink) may especially be a passive heat exchanger that transfers the heat generated by device, such as an electronic device or a mechanical device, to a fluid (cooling) medium, often air or a liquid coolant. Thereby, the heat is (at least partially) dissipated away from the device. A heat sink is especially designed to maximize its surface area in contact with the fluid cooling medium surrounding it. Hence, especially a heatsink may comprise a plurality of fins. For instance, the heatsink may be a body with a plurality of fins extending thereof. A heatsink especially comprises (more especially consists of) a thermally conductive material. The term “heatsink” may also refer to a plurality of (different) heatsinks.

Further, the thermally conductive element may comprise a heat spreader. A heat spreader may be configured to transfer energy as heat from a first element to a second element. The second element may especially be a heatsink or heat exchanger. A heat spreader may passive or active. Embodiments of passive heat spreaders may comprise a plate or block of material having high thermal conductivity, such as copper, aluminum, or diamond. An active heat spreader may be configured to speed up heat transfer with expenditure of energy as work supplied by an external source. Herein, the heat spreader may especially be a passive heat spreader. Alternatively or additionally, the heat spreader may be an active heat spreader, such as selected from the group of heat pipes and vapor chambers. A heat spreader especially comprises (more especially consists of) a thermally conductive material. The term “heat spreader” may also refer to a plurality of (different) heat spreaders.

Moreover, the thermally conductive element may comprise a two-phase cooling device. Two-phase cooling devices may be devices that transfer heat between two locations based on both thermal conductivity and phase transition. In particular, liquid, such as water (e.g. for a copper device) or acetone (e.g. for an aluminum device), may be added to the two-phase cooling device and the two-phase cooling device may be vacuum sealed. When heat is applied to one area of the two-phase cooling device, the liquid may turn to vapor and move to an area of lower pressure where it cools and returns to liquid form whereupon it moves back to the heat source.

In embodiments, the two-phase cooling device may especially comprise a heat pipe or a vapor chamber element. Vapor chamber elements and heat pipes are known in the art and may be based on essentially the same principle. A difference between the heat pipe and the vapor chamber element may be that the heat pipe may typically have an essentially rod-shaped shape, whereas the vapor chamber element may in general have a planar shape. In particular, the vapor chamber element may include two essentially planar plates at a relative short distance (such as up to 5 mm). Further, for the vapor chamber element the hot spot may relatively freely be chosen, whereas for a heat pipe there is generally a hot and cold side at the opposing sides of the rod, such as at the bases of a cylinder-shaped heat pipe.

The two-phase cooling device may have a device wall, especially wherein the device wall defines an elongated chamber. In particular, the device wall may enclose the chamber. The device wall may generally be airtight. The device wall may especially comprise a thermally conductive material. A two-phase cooling device configured for functional coupling to a luminescent body may especially have a device wall comprising a thermally conductive material selected from the group comprising copper, aluminum, stainless steel, nickel and titanium, which may be particularly suitable for the operational temperatures of such a system.

Both heat pipes and vapor chambers are two-phase devices used as thermal management solutions. A heat pipe may be a device with high thermal conductance that can transport large amounts of heat with a slight temperature difference between its hot and cold ends. On the other hand, a vapor chamber may be composed of flat heat pipes with very high thermal conductance, having flat surfaces on the top and bottom sides. When compared to traditional solutions like copper heat spreaders, heat pipes and vapor chambers have many strengths. First, they have a higher thermal conductivity. Second, the density of the heat pipe and vapor chamber is much lower than that of copper. Because of its hollow structure, the heat spreaders made by vapor chambers are much lighter than those made of copper. These properties make them stand out as ideal thermal management solutions. Strength of a heat pipe may be: high conductance and flexible in design. Strengths of a vapor chamber may be: high conductance, capable of transferring a large amount of heat, can be made very thin, the heat transfer can stay efficient even when a heat source is high, the planate structure is capable of diffusing heat instantaneously, even for a large area. Both devices have excellent heat transport efficiency for dissipating heat. While heat pipes may remove heat from the heat source, vapor chambers spread heat. As for heat pipes, they may be bent and installed in all directions. This provides heat pipes with design flexibility and enables them to be used alone, in combination, and in different positions. Vapor chambers may also be bent. Vapor chamber may be planar which may have impact on the freedom to bend the vapor chamber.

Herein, in embodiments the second thermally conductive element, especially the two-phase cooling device, may in embodiments be arranged in a part of the second support away from the array of through-holes in the second support, e.g., a heat pipe running between the array of through-holes. Further, in such embodiments, a two-phase cooling device may specifically be bent around the through-holes. In other embodiments, the second thermally conductive element may be designed comprising an array of openings aligned with the array of through-holes in the second support. As will be clear to a person skilled in the art, the two-phase cooling device is closed, and the through-holes are not in fluid communication with the internal of the two-phase cooling device.

Further, in embodiments, the first thermally conductive element, especially the two-phase cooling device, may in embodiments arranged in a part of the first support away from the light sources, e.g., a heat pipe running in between the array of light sources (such as in a canned laser configuration). Further, in such embodiments, a two-phase cooling device may specifically be bent around the array of light sources. In other embodiments, the first thermally conductive element may be designed comprising an array of openings for the light sources (such as in a canned laser configuration). In yet further embodiments, the first thermally conductive element may be configured on a bottom side of the first support, e.g., a heat spreader, heat sink and air-blowing fan configured on the bottom side of a first support comprising (diode) lasers.

Hence, the first support may have a supporting function for the first light sources and may have a thermal function. To this end, the first light sources may be configured on, or at least partly in a first thermally conductive element. Likewise, the second support may have a supporting function for the second light sources and may have a thermal function. To this end, the second light sources may be configured on, or at least partly in a second thermally conductive element. However, the second support may further also have the function of providing through-holes.

Hence, each of the supports may comprise a thermally conductive body, a heat sink, a heat spreader, or (other) two-phase cooling device. Further, the (respective) light sources may be configured at least partially in, or on the respective support.

Other elements known to the skilled person may yet be configured on, coupled to, or supported by the support, or comprised by the support. For example, a light source may especially be connected to a power source via a support. In some embodiments, a power source may be configured on the support. However, alternatively a power source may in embodiments also be configured external to a support. Hence, in embodiments the support may comprise a metal core printed circuit board (which may be a thermally conductive element as such). In yet other embodiments, the support may comprise a printed circuit board thermally coupled to a thermally conductive element. In other embodiments, the support may comprise a metal-core printed circuit board thermally coupled to a thermally conductive element.

In (yet other) embodiments, the light sources may at least partly embedded in a thermally conductive element.

In embodiments, the light generating system may comprise first light sources and second light sources. The first light sources may be arranged on the first support and the second light sources may be arranged on the second support. Especially, each set of light sources may be arranged on each support in a 2D array (or: “matrix”). The 2D array may in embodiments be a rectangular array, a square array, a circular array, etc. Thereby, the light generating system may comprise a first 2D array of first light sources and a second 2D array of second light sources.

In embodiments, the light generating system may comprise a light source. A light source may in particular be a first light source or a second light source. A light source may further be configured to generate light. Therefore, the first light sources may be configured to generate first light source light and the second light sources may be configured to generate second light source light. The light source may especially be a laser diode (or “diode laser”)). The term “light source” may refer in embodiments to a vertical cavity laser diode (VCSELs), an edge emitting laser, etc.

The term “light source” may also relate to a plurality of light sources, such as 2-2000 (laser diode) light sources. The phrases “different light sources” or “a plurality of different light sources”, and similar phrases, may in embodiments refer to a plurality of solid-state light sources selected from at least two different bins. Likewise, the phrases “identical light sources” or “a plurality of same light sources”, and similar phrases, may in embodiments refer to a plurality of solid-state light sources selected from the same bin.

The term “laser light source” especially refers to a laser. Such laser may especially be configured to generate laser light source light having one or more wavelengths in the UV, visible, or infrared, especially having a wavelength selected from the spectral wavelength range of 200-2000 nm, such as 300-1500 nm. The term “laser” especially refers to a device that emits light through a process of optical amplification based on the stimulated emission of electromagnetic radiation. In embodiments, the term “laser” may refer to a solid-state laser. In specific embodiments, the terms “laser” or “laser light source”, or similar terms, refer to a laser diode (or diode laser). Especially, the first light sources may comprise laser diodes and the second light sources may comprise laser diodes.

Hence, in embodiments the light source comprises a laser light source. In embodiments, the terms “laser” or “solid state laser” or “solid state material laser” may refer to one or more of cerium doped lithium strontium (or calcium) aluminum fluoride (Ce:LiSAF, Ce:LiCAF), chromium doped chrysoberyl (alexandrite) laser, chromium ZnSe (Cr:ZnSe) laser, divalent samarium doped calcium fluoride (Sm:CaF₂) laser, Er:YAG laser, erbium doped and erbium-ytterbium codoped glass lasers, F-Center laser, holmium YAG (Ho:YAG) laser, Nd:YAG laser, NdCrYAG laser, neodymium doped yttrium calcium oxoborate Nd:YCa₄O(BO₃)₃ or Nd:YCOB, neodymium doped yttrium orthovanadate (Nd:YVO₄) laser, neodymium glass (Nd:glass) laser, neodymium YLF (Nd:YLF) solid-state laser, promethium 147 doped phosphate glass (147Pm³⁺:glass) solid-state laser, ruby laser (Al₂O₃:Cr³⁺), thulium YAG (Tm:YAG) laser, titanium sapphire (Ti:sapphire; Al₂O₃:Ti³⁺) laser, trivalent uranium doped calcium fluoride (U:CaF₂) solid-state laser, Ytterbium doped glass laser (rod, plate/chip, and fiber), Ytterbium YAG (Yb:YAG) laser, Yb₂O₃ (glass or ceramics) laser, etc.

For instance, including second and third harmonic generation embodiments, the light source may comprise one or more of an F center laser, an yttrium orthovanadate (Nd:YVO₄) laser, a promethium 147 doped phosphate glass (147Pm³⁺:glass), and a titanium sapphire (Ti:sapphire; Al₂O₃:Ti³⁺) laser. For instance, considering second and third harmonic generation, such light sources may be used to generated blue light.

In embodiments, the terms “laser” or “solid state laser” or “solid state material laser” may refer to one or more of a semiconductor laser diodes, such as GaN, InGaN, AlGaInP, AlGaAs, InGaAsP, lead salt, vertical cavity surface emitting laser (VCSEL), quantum cascade laser, hybrid silicon laser, etc.

A laser may be combined with an upconverter in order to arrive at shorter (laser) wavelengths. For instance, with some (trivalent) rare earth ions upconversion may be obtained or with non-linear crystals upconversion can be obtained. Alternatively, a laser can be combined with a downconverter, such as a dye laser, to arrive at longer (laser) wavelengths.

The term “solid state material laser”, and similar terms, may refer to a solid state laser like based on a crystalline or glass body dopes with ions, like transition metal ions and/or lanthanide ions, to a fiber laser, to a photonic crystal laser, to a semiconductor laser, such as e.g. a vertical cavity surface-emitting laser (VCSEL), etc.

As can be derived from the below, the term “laser light source” may also refer to a plurality of (different or identical) laser light sources. In specific embodiments, the term “laser light source” may refer to a plurality N of (identical) laser light sources. In embodiments, N=2, or more. In specific embodiments, N may be at least 5, such as especially at least 8. In this way, a higher brightness may be obtained.

In embodiments, the (laser) light source may be arranged in a laser bank (see also above). The (laser) light sources may especially be arranged in a 2D array in the laser bank. The laser bank may in embodiments comprise a support, heat sinking, and optical elements e.g. a lens to collimate the laser light. Hence, in embodiments lasers in a laser bank (or “laser array bank”) may share the same support, heat sinking, and optical elements.

The (laser) light source may especially be configured to generate light source light having an optical axis (O), (a beam shape,) and a spectral power distribution. The light source light may in embodiments comprise one or more bands, having band widths as known for lasers. The laser light source is hence configured to generate laser light source light (or “laser light”). The light source light may essentially consist of the laser light source light. The light source light may also comprise laser light source light of two or more (different or identical) laser light sources. For instance, the laser light source light of two or more (different or identical) laser light sources may be coupled into a light guide, to provide a single beam of light comprising the laser light source light of the two or more (different or identical) laser light sources. In specific embodiments, the light source light is thus especially collimated light source light. In yet further embodiments, the light source light is especially (collimated) laser light source light.

The laser light source light may in embodiments comprise one or more bands, having band widths as known for lasers. In specific embodiments, the band(s) may be relatively sharp line(s), such as having full width half maximum (FWHM) in the range of less than 20 nm at RT, such as equal to or less than 10 nm. Hence, the light source light has a spectral power distribution (intensity on an energy scale as function of the wavelength) which may comprise one or more (narrow) bands.

The beams (of light source light) may be focused or collimated beams of (laser) light source light. The term “focused” may especially refer to converging to a small spot. This small spot may be at the discrete converter region, or (slightly) upstream thereof or (slightly) downstream thereof. Especially, focusing and/or collimation may be such that the cross-sectional shape (perpendicular to the optical axis) of the beam at the discrete converter region (at the side face) is essentially not larger than the cross-section shape (perpendicular to the optical axis) of the discrete converter region (where the light source light irradiates the discrete converter region). Focusing may be executed with one or more optical elements, like (focusing) lenses. Especially, two lenses may be applied to focus the laser light source light. Collimation may be executed with one or more (other) optical elements, like collimation elements, such as lenses and/or parabolic mirrors. In embodiments, the beam of (laser) light source light may be relatively highly collimated, such as in embodiments ≤2° (FWHM), more especially ≤1° (FWHM), most especially ≤0.5° (FWHM). Hence, ≤2° (FWHM) may be considered (highly) collimated light source light. Optical elements may be used to provide (high) collimation (see also above). Herein, the term “optical elements” may especially refer to optics that affect beam shaping, e.g., collimation and/or focusing of light. Each laser bank may comprise one or more optical elements. Therefore, the light generating system may in embodiments comprise first optical elements and second optical elements. In embodiments, the first optical elements may be configured downstream of the first light sources. Further, the first optical elements may be configured to collimate the first light source light into first beams of collimated first light source light. In embodiments, the second optical elements may be configured downstream of the second light sources. Moreover, the one or more second optical elements may be configured to collimate the second light source light into second beams of collimated second light source light. Hence, the light source light may be provided as (highly) collimated light source light.

The terms “upstream” and “downstream” relate to an arrangement of items or features relative to the propagation of the light from a light generating means (here the especially the light source), wherein relative to a first position within a beam of light from the light generating means, a second position in the beam of light closer to the light generating means is “upstream”, and a third position within the beam of light further away from the light generating means is “downstream”.

Other optics known to the skilled person may be provided. Such other optics may include e.g. wavelength converting optics (such as dichroic elements, i.e. the wavelength converting element described in U.S. Pat. No. 7,070,300B2 which is hereby incorporated for reference) or polarizing optics (such as reflective polarizers).

In embodiments, the laser arrangements may be in a stacked configuration. Thereby, the first support and the second support may be configured stacked. Especially, the second support may be configured stacked over the first support. Therefore, the second support may be configured downstream of the first light source light. The second support may in embodiments comprise an array of through-holes, especially an opening array of through-holes. The through-holes may be provided in a variety of shapes, e.g. cylindrical-shaped, rectangle-shaped, truncated cone-shaped, etc. In embodiments, the through-holes may especially have a cylindrical shape. Especially, the through-holes may have an elongated cylindrical shape. In specific embodiments, the through-hales may have another elongated shape, e.g., an elongated rectangular shape, an elongated truncated cone shape, etc. In general, the through-holes in the array of through-holes may (essentially) have the same shape. In specific embodiments, the array of through-holes may comprise through-holes with different shapes. The array of through-holes may especially be configured downstream of the light source light. As such, the first light source light may be able to propagate through the second support via the array of through-holes (in the second support). Further, the array of through-holes may be configured aligned with the first optical elements. Thereby, the array of through-holes may be configured to allow propagation of at least part of the collimated first light source light through the second support via the array of through-holes. Hence, the array of through-holes facilitates propagation of first light source light in a stacked laser bank configuration. In particular, the first 2D array of the first light sources may correspond to the pattern of through-holes (of the second support).

The light generating system may thereby in embodiments be configured to generate system light. The system light may especially comprise one or more of the (collimated) first light source light (propagated through the second support via the array of through-holes) and the (collimated) second light source light. In particular, the system light may comprise both the (collimated) first light source light and the (collimated) second light source light. The system light may in specific embodiments comprise converted system light.

In specific embodiments, the second support may comprise second cavities. The second cavities may be provided in a variety of shapes, e.g. cylindrical-shaped, square-shaped, truncated cone-shaped, etc. In general, the second cavities in the second support may (essentially) have the same shape. The cavities may be configured to host at least a subset of the first optical elements. Especially, the cavities may be configured to host at least part of the total number of the first optical elements. In further embodiments, the second cavities may be configured to host the total number of the first optical elements. In specific embodiments, the second cavities may be configured to additionally host at least a subset of the first light sources. Moreover, the second cavities may be configured to additionally host the total number of first light sources. The second cavities may especially be configured upstream of the array of through-holes. That is, the first light source light may first propagate through the second cavities before entering the array of through-holes. In other embodiments, the second cavities may comprise the through-holes. That is, the second cavities may be through-holes in the second support configured to (i) host at least a subset of the total number of the first optical elements, and (ii) allow propagation of at least part of the collimated first light source light through the second support. Hence, the second cavities may provide a configuration within the second support for the first optical elements to be downstream from the first light sources and upstream of the through-holes.

Herein, the first support and the second support may especially have a top side and a bottom side. The top side and bottom side of a support may especially be defined in relation to the direction of the light source light, i.e., the top side may be in the same direction as downstream of the light source light relative to the bottom side. Specifically, in embodiments the light sources may be configured on the top side of a support; though they may in other embodiments at least partly reside in cavities in the top side of the support. In further embodiments, a top side of the first support and a bottom side of the second support may be configured in contact with each other. Especially, in specific embodiments the top side of the first support and the bottom side of the second support may be configured in physical contact with each other. The distance (d₁) between the top side of the first support and the bottom side of the second support may be (essentially) 0 mm. In such configuration, the first light sources may especially be hosted by the second cavities. Thereby, the light sources may be hosted in the second cavities when the first support and the second support are configured in contact with each other. Hence, the second cavities may be configured to conform to the 2D array of the first light sources. Thereby, the second optical elements may be recessed in this configuration to make good thermal contact and hence improve thermal management.

In other embodiments where the top side of the first support and the bottom side of the second support are configured in contact with each other, the first support may additionally comprise first cavities configured to host the first light sources. In such embodiments, the first light sources may be hosted by the first cavities in the first support and the first optical elements may be hosted by second cavities in the second support. In specific other embodiments, the first light sources and the first optical elements may be hosted by the first cavities in the first support.

In yet other embodiments, however, the top side of the first support and the bottom side of the second support may be configured at a non-zero distance (d₁) from each other. The non-zero distance (d₁) may be selected from the range of 0.1-200 mm, such as from the range of 0.5-100 mm, especially from the range of 1-10 mm. In such embodiments, the first light sources may especially be configured within the non-zero distance (d₁) space. The first light sources may in specific embodiments yet be configured at least partially in the first cavities or the second cavities. Especially, the first light sources and the one or more first light optics may be configured such that the first light source light reaches the through-holes of the second support. Thereby, the non-zero distance may allow for airflow through the light generating system and hence improved thermal management.

In certain embodiments, the through-holes may have hole axes. The hole axes may especially be configured parallel to the path of the (collimated) first light source light. The through-holes may have circular equivalent diameters (D_{C}). The through-holes may especially have largest circular equivalent diameters (D_{C1}). The equivalent circular diameter (or ECD) (or “circular equivalent diameter”) of an (irregularly shaped) two-dimensional shape is the diameter of a circle of equivalent area. For instance, the equivalent circular diameter of a square with side a is 2*a*SQRT(1/π). For a circle, the diameter is the same as the equivalent circular diameter. Would a circle in an xy-plane with a diameter D be distorted to any other shape (in the xy-plane), without changing the area size, than the equivalent circular diameter of that shape would be D. The largest circular equivalent diameters D_{C1} may especially be defined perpendicular to the hole axes. The largest circular equivalent diameters D_{C1} may be selected from the range of 0.1-5 mm, such as 0.5-3 mm, especially 1-2 mm. Most especially, the largest circular equivalent diameters (D_{C1}) may be at maximum 5 mm. When the through-hole is cylindric, over the entire height of the through-hole the diameter is essentially constant. Hence, the largest circular equivalent diameter is also the smallest circular equivalent diameter as the diameter is constant over the height. However, in the case of a conically shaped through-hole, the diameter may increase or decrease over the height. Then, the largest diameter is the largest circular equivalent diameters (D_{C1}). Similarly this may apply to through-holes having non-circular cross-sections.

In some embodiments, the circular equivalent diameter D_{C} may (essentially) remain the same along the through-holes, e.g., when the through-holes have a cylindrical shape. In such embodiments, the circular equivalent diameter D_{C} along the through-hole is (essentially) identical to the largest circular equivalent diameter D_{C1}. In other embodiments, the circular equivalent diameter D_{C} may change along the through-hole, e.g., when the through-holes are truncated cone-shaped. In such embodiments, the through-hole may have both the largest circular equivalent diameter D_{C1} and a smallest circular equivalent diameter (D_{C2}). The circular equivalent diameters D_{C2} may also be defined perpendicular to the hole axes. Further, the smallest circular equivalent diameters D_{C2} may be selected from the range of 0.1-5 mm, such as 0.5-3 mm, especially 1-2 mm. Hence, the through-holes may allow sufficient heatsinking for cooling the light sources.

In further embodiments, the optical elements may be comprised by a monolithic optical body, such as a lens plate. Especially, the second optical elements may be comprised by a monolithic optical body. Such monolithic optical body comprising second optical elements may herein be referred to as a second monolithic optical body. The second monolithic optical body may comprise optical body through-holes. Such optical body through-holes may be provided in a variety of shapes, e.g. cylindrical-shaped, square-shaped, truncated cone-shaped, etc. In embodiments, the optical body through-holes may especially have a cylindrical shape, such as an (elongated) cylindrical shape. In general, the optical body through-holes may (essentially) have the same shape. In specific embodiments, the optical body through-holes may comprise optical body through-holes with different shapes. The optical body through-holes may especially be aligned with the through-holes of the second support. Further, the optical body through-holes may also be aligned with the path of the first light source light. Additionally or alternatively, the optical body through-holes of the second support may be aligned with the path of the second light source light. Further, in specific embodiments, a monolithic optical body comprising first optical elements may herein be referred to as a first monolithic optical body. Such first monolithic optical body may optionally comprise first optical body through-holes. The monolithic body may also be indicated as lens plate.

In certain embodiments, the first 2D array may have a first array pitch (P₁). Further, the second 2D array may further have a second array pitch (P₂). The array pitch may herein be defined as the distance between individual light sources in the 2D array. The array pitch(es) may be selected from the range of 0.1-20 mm, such as from the range of 0.5-10 mm, especially from the range of 1-5 mm. Further, the light generating system may have an overall pitch (P_{A}) of light sources, i.e., the distance between the center of the individual light sources selected from both the first light sources and the second light sources. In certain embodiments, the first array pitch P₁ and the second array pitch P₂ may be different. In embodiments, the first array pitch P₁ and the second array pitch P₂ may be (essentially) identical. In such embodiments, the first array pitch P₁ and the second array pitch P₂ may in embodiments have a mutual angle (α) of 90°. In such embodiments, P_{A}=0.5*P₁. Further, P_{A}=0.5*P₂.

In embodiments, wherein the first 2D array may have a first array pitch P1, the second 2D array may have a second array pitch P2, and one or more of the following may apply: (a) the first array pitch and the second array pitch have a mutual angle (α) of 90°, and (b) the light generating system has an overall pitch P_{A} of light sources, wherein Pa=0.5*P1.

In the invention, the intensity of system light may be improved as the packing of light sources may be increased (such as doubled) compared to a single laser bank. Hence, the stacking may lead to a high intensity light source.

In embodiments, by rotating the second laser-bank with respect to the first laser-bank the laser-banks may be stacked because the through-holes and light sources are aligned in a rotated configuration. Hence, when using identical types of laser banks, comprising holes, which together with the light sources are configured in arrays, the two arrays can be stacked, in specific embodiments after a rotation of 90°.

Another option would be to use two different types of laser banks, wherein the configuration of the light sources of one may differ from the other one, to allow through-holes in the second laser bank being configured downstream of the light sources comprised by the first laser bank.

In specific embodiments, the first 2D array and/or the second 2D array may (thus) be a square array. In other embodiments, the first 2D array and/or the second 2D array may be a (non-square) rectangular array. Other type of arrays may be possible as well.

A (rectangular) array may have an array longest pitch (P_{L}) and an array shortest pitch (P_{S}). For some rectangular arrays, especially square arrays, the array longest pitch (P_{L}) and an array shortest pitch (P_{S}) may be essentially identical. For other (rectangular) arrays, the array longest pitch (P_{L}) and an array shortest pitch (P_{S}) may be different. Thereby, the first 2D array may have a first array longest pitch (P_{L1}) and a first array shortest pitch (P_{S1}). Further, the second 2D array may have a second array longest pitch (P_{L2}) and a second array shortest pitch (P_{S2}). Further, the light generating system may have an overall longest pitch (P_{LA}) and an overall shortest pitch (P_{SA}) of light sources, i.e., the pitches based on the combination of the first light sources and the second light sources, i.e. the pitch when viewing in an upstream direction to the second support. When both arrays are square, the overall pitches may be identical.

In embodiments, the first array longest pitch P_{1L} and the second array longest pitch P_{2L} may have a mutual angle (α) unequal to 0° or 180°. The mutual angle (α) may in such embodiments be 60° or 90°. In specific embodiments, P_{LA}=0.5*P_{L1}. Further, P_{LA}=0.5*P_{L2}. Moreover, in (such) embodiments, P_{SA}=0.5*P_{S1} and P_{SA}=0.5*P_{S2}. Thereby, the density of light sources may be improved as the packing of light sources may be increased (such as doubled) compared to a single laser bank.

In further embodiments, the first light source light and the second light source light differ in their centroid wavelength. In such embodiments, the first light sources may be essentially identical light sources (especially in terms of the light source light generated). Further, the second light sources may be essentially identical light sources (especially in terms of the light source light generated). However, the first light sources and the second light sources may be different light sources (especially in terms of the light source light generated). In such embodiments, the centroid wavelength of the first light source light and the second light source light may differ at least 5 nm, such as at least 10 nm, especially at least 20 nm. Especially, the wavelengths of the first light source light and the second light source light may be selected such that the system light (comprising the first light source light and the second light source light) is high intensity white light.

The term “centroid wavelength”, also indicated as λc, is known in the art, and refers to the wavelength value where half of the light energy is at shorter and half the energy is at longer wavelengths; the value is stated in nanometers (nm). It is the wavelength that divides the integral of a spectral power distribution into two equal parts as expressed by the formula λc=Σλ*I(λ)/(ΣI(λ)), where the summation is over the wavelength range of interest, and I(λ) is the spectral energy density (i.e. the integration of the product of the wavelength and the intensity over the emission band normalized to the integrated intensity). The centroid wavelength may e.g. be determined at operation conditions.

In certain embodiments, the first light source light and the second light source light may differ in their color point. In specific embodiments, colors, or color points of the first light source light and the second light source light may be essentially the same when the respective color points of the first type of light and the second type of light differ with at maximum 0.03 for u′ and/or with at maximum 0.03 for v′, even more especially at maximum 0.02 for u′ and/or with at maximum 0.02 for v′. In yet more specific embodiments, the respective color points of first type of light and the second type of light may differ with at maximum 0.01 for u′ and/or with at maximum 0.01 for v′. Here, u′ and v′ are color coordinate of the light in the CIE 1976 UCS (uniform chromaticity scale) diagram. Alternatively, the color points may be expressed as coordinates in the CIE1931 color space chromaticity diagram.

In specific embodiments, the first light sources may comprise at least two different types of first light sources. Further, the second light sources may comprise at least two different types of second light sources. The two different types of first light sources may also differ in one or more of centroid wavelength and color point. The two different types of second light sources may differ in one or more of centroid wavelength and color point. In embodiments, the centroid wavelength of the first light source light of the at least two different types of first light sources may differ at least 5 nm, such as at least 10 nm, especially at least 20 nm. The u′ and/or v′ of the color points of the first light source light of the at least two different types of first light sources may especially differ with at least 0.01, such as at least 0.03, especially at least 0.05. Further, in embodiments, the centroid wavelength of the second light source light of the at least two different types of second light sources may differ at least 5 nm, such as at least 10 nm, especially at least 20 nm. The u′ and/or v′ of the color points of the second light source light of the at least two different types of second light sources may especially differ with at least 0.01, such as at least 0.03, especially at least 0.05. In this way, it may be possible to provide e.g. RGB solutions, or other white light solutions, with laser diodes. Each laser arrangement may provide an RGB solution, or other white light solution, with laser diodes, or the laser arrangements together may provide an RGB solution, or other white light solution, with laser diodes.

In specific embodiments, the first optical elements and the second optical elements may comprise aspheric lenses (also: “aspherical lenses”). An aspheric lens is a rotationally symmetric lens whose surface profile is more complex compared to spherical lenses (or: “simple lenses”), i.e., the surface profile of aspheric lenses cannot be described as part of a single sphere or single cylinder. In the context of (diode) lasers, aspheric lenses may especially be used for the collimation of light. Most especially, aspheric lenses may collimate laser light such that the collimated laser light has a spherical beam shape. Aspheric lenses may additionally be used to correct for light aberrations that may arise from the use of spherical lenses. Hence, first aspheric lenses may be used for generating collimated first light source light with a spherical beam shape without light aberrations. Further, second aspheric lenses may be used for generating collimated second light source light with a spherical beam shape without light aberrations.

Further, the first optical elements and the second optical elements may be arranged at 90°. Especially, the first aspherical lenses and the second aspherical lenses may be arranged at 90°.

In embodiments, the first laser arrangement may be or may be comprised by a first laser bank. Alternatively or additionally, in embodiments, the second laser arrangement may be or may be comprised by a second laser bank.

When lasers are collimated with spherical lenses, the cross-sectional shape of the beams may especially be rectangular. As a result, the packing density of the beams may be higher in one direction of the laser bank over another orthogonal direction of the laser bank. In such embodiments, the through-holes may in particular be configured in the direction with lower density between lasers. Therefore, a higher packing density may be facilitated to achieve higher light intensities.

In embodiments, laser banks may be applied. Laser banks may also be used to boast the input power. Therefore, in embodiments the system may comprise a plurality of light generating devices configured in a laser bank. A laser bank may comprise a light emitting arrangement comprising an (2D) array of a plurality of laser diodes arranged on a thermally conductive carrier and a (lens array having a) plurality of collimator lenses corresponding to the laser diodes such that each laser diode of the plurality of laser diodes comprises a collimator lens for collimating laser light emitted by the laser diode. The arrangement may comprise a package architecture or a canned architecture. In case of the package architecture a laser diode chip array is arranged on the thermally conductive carrier. A plurality of electrodes may be present for electrically connecting the plurality of laser diodes.

Hence, in further embodiments, the first laser bank comprises the first support, the first 2D array of first light sources, and the first optical elements. Especially, a second laser bank may comprise the second support, the second 2D array of second light sources, and the second optical elements.

In particular, the first optical elements (e.g. first aspherical lenses) comprised by the first laser bank may be configured to collimate the first light source light into first beams of collimated first light source. The first light source light may have a full width half maximum (FWHM) from the range of 10°-30° prior to being collimated. Further, the cross-sectional shape of (a beam of) light source light may be elliptical, e.g. with—in embodiments—a shorter axis in the range of about 10° FWHM and a larger axis in the range of about 30° FWHM. The collimated first light source light may especially have a first full width half maximum (FWHM) defined beam angle (β₁). The first FWHM defined beam angle (β₁) may be at maximum (i.e. not more than) 3°, such as at maximum 2°, especially at maximum 1.5°. Using (first) aspherical lenses may lead to collimated light source light having a less elliptical shape. Further, using the aspherical lenses may provide substantially collimated light source light.

Additionally or alternatively, the second optical elements (e.g. second aspherical lenses) comprised by the second laser bank may be configured to collimate the second light source light into second beams of collimated second light source. The second light source light may have a full width half maximum from the range of 10°-30° prior to being collimated. Further, the cross-sectional shape of (a beam of) light source light may be elliptical, e.g. with—in embodiments—a shorter axis in the range of about 10° FWHM and a larger axis in the range of about 30° FWHM. The collimated second light source light may especially have a second full width half maximum (FWHM) defined beam angle (β₂). The second FWHM defined beam angle (β₂) may be at maximum 3°, such as at maximum 2°, especially at maximum 1.5°. Using (second) aspherical lenses may lead to collimated light source light having a less elliptical shape. Further, using the aspherical lenses may provide substantially collimated light source light.

In certain embodiments, the light generating system may further comprise a homogenizer element. Such homogenizer element may especially comprise a beam homogenizer, i.e., an element configured to homogenize (laser) beams with an irregular energy profile (such as a Gaussian energy distribution) and provide (laser) beams with an evenly distributed energy profile. Herein, the homogenizer element may in particular be configured to homogenize the first beams of collimated first light source light together with the second beams of collimated second light source light. Therefore, the homogenizer element may be configured downstream of the first optics and the second optics. In this way, light source light of the laser light sources may only escape via the homogenizer element. Hence, the homogenizer element may provide system light comprising a more uniform (laser) beam.

In further embodiments, the light generating system may comprise a system light window. Such system light window may be transparent and configured for outcoupling of the (homogenized) light source light as system light. The system light window may therefore be arranged downstream of the homogenizer element. Such system light window may in embodiments be provided as part of a light device (described further below). In certain embodiments, the system light window may comprise the homogenizer element. In some embodiments, the system light window may be the homogenizer element.

In embodiments, the light generating system may be configured to provide in an operational mode of the light generating system light comprising the first light source light and/or the second light source light. In yet further embodiments the light generating system may be configured to provide in a further operational mode of the light generating system light comprising the first light source light and the second light source light. In specific embodiments, the system light may comprise the homogenized light provided by the homogenizer element (after homogenizing the collimated light source light). Further, the system light may especially be provided after outcoupling through a system light window.

The first light sources and/or the second light sources may be controlled. In other embodiments, subset of first light sources may individually be controlled and/or subset of second light sources may individually be controlled. Hence, the first light sources and the second light sources may in embodiments be controlled. Therefore, the light generating system may comprise a control system or may be functionally coupled to a control system.

The term “controlling” and similar terms especially refer at least to determining the behavior or supervising the running of an element. Hence, herein “controlling” and similar terms may e.g. refer to imposing behavior to the element (determining the behavior or supervising the running of an element), etc., such as e.g. measuring, displaying, actuating, opening, shifting, changing temperature, etc. Beyond that, the term “controlling” and similar terms may additionally include monitoring. Hence, the term “controlling” and similar terms may include imposing behavior on an element and also imposing behavior on an element and monitoring the element. The controlling of the element can be done with a control system, which may also be indicated as “controller”. The control system and the element may thus at least temporarily, or permanently, functionally be coupled. The element may comprise the control system. In embodiments, the control system and element may not be physically coupled. Control can be done via wired and/or wireless control. The term “control system” may also refer to a plurality of different control systems, which especially are functionally coupled, and of which e.g. one control system may be a master control system and one or more others may be slave control systems. A control system may comprise or may be functionally coupled to a user interface.

The control system may also be configured to receive and execute instructions from a remote control. In embodiments, the control system may be controlled via an App on a device, such as a portable device, like a Smartphone or I-phone, a tablet, etc. The device is thus not necessarily coupled to the lighting system, but may be (temporarily) functionally coupled to the lighting system.

Hence, in embodiments the control system may (also) be configured to be controlled by an App on a remote device. In such embodiments the control system of the lighting system may be a slave control system or control in a slave mode. For instance, the lighting system may be identifiable with a code, especially a unique code for the respective lighting system. The control system of the lighting system may be configured to be controlled by an external control system which has access to the lighting system on the basis of knowledge (input by a user interface of with an optical sensor (e.g. QR code reader) of the (unique) code. The lighting system may also comprise means for communicating with other systems or devices, such as on the basis of Bluetooth, Thread, WIFI, LiFi, ZigBee, BLE or WiMAX, or another wireless technology.

The system, or apparatus, or device may execute an action in a “mode” or “operation mode” or “mode of operation” or “operational mode”. The term “operational mode may also be indicated as “controlling mode”. Likewise, in a method an action or stage, or step may be executed in a “mode” or “operation mode” or “mode of operation” or “operational mode”. This does not exclude that the system, or apparatus, or device may also be adapted for providing another controlling mode, or a plurality of other controlling modes. Likewise, this may not exclude that before executing the mode and/or after executing the mode one or more other modes may be executed.

However, in embodiments a control system may be available, that is adapted to provide at least the controlling mode. Would other modes be available, the choice of such modes may especially be executed via a user interface, though other options, like executing a mode in dependence of a sensor signal or a (time) scheme, may also be possible. The operation mode may in embodiments also refer to a system, or apparatus, or device, that can only operate in a single operation mode (i.e. “on”, without further tunability).

Hence, in embodiments, the control system may control in dependence of one or more of an input signal of a user interface, a sensor signal (of a sensor), and a timer. The term “timer” may refer to a clock and/or a predetermined time scheme.

As indicated above, it may be possible to provide e.g. RGB solutions, or other white light solutions, with (diode) lasers. Downstream of the laser arrangement, a diffuser element may be configured. In this way, light source light of the laser light sources may only escape via the diffuser element. In embodiments, system light may thus essentially consist of first light source light and/or second light source light escaped from the system via the diffuser element. Especially, the diffuser element may be configured downstream of the first light sources and/or the second light sources. Thereby, the diffuser element may be configured to diffuse at least part of the first light source light into diffused light. Additionally or alternatively, the diffuser element may be configured to diffuse at least part of the second light source light into diffused light. The diffused light may hence comprise at least part of the first light source light and/or part of the second light source light. The system light may comprise (a) one or more of first light source light and second light source light, and (b) diffused light.

However, additionally or alternatively, a luminescent material (especially a phosphor-based luminescent material) may be applied, to convert at least part of the light source light. The luminescent material may be configured to convert at least part of the first light source light and/or at least of the second light source light into luminescent material light, wherein the luminescent material is configured downstream of the first light sources and the second light sources. This may in specific embodiments lead to white system light. Such white system light may comprise (a) one or more of first light source light and second light source light, and (b) luminescent material light.

Especially, the light generating system may be configured to provide—in an operational mode of the light generating system-system light comprising the luminescent material light, the first light source light and/or the second light source light. Yet, in embodiments, the light generating system may be configured to provide—in an operational mode of the light generating system-system light comprising the diffused light, the first light source light and/or the second light source light. Furthermore, in embodiments, the light generating system may be configured to provide—in an operational mode of the light generating system—system light comprising the luminescent material light and the diffused light. Especially, the system light may comprise (a) the luminescent material light, (b) the diffused light, and (c) one or more of first light source light and second light source light. In specific embodiments, the system light may be white light having a color rendering index of at least 80 and a correlated color temperature selected from the range of 1800-10000 K.

The terms “visible”, “visible light” or “visible emission” and similar terms refer to light having one or more wavelengths in the range of about 380-780 nm. Herein, UV may especially refer to a wavelength selected from the range of 190-380 nm, such as 200-380 nm.

The term “white light”, and similar terms, herein, is known to the person skilled in the art. It may especially relate to light having a correlated color temperature (CCT) between about 1800 K and 20000 K, such as between 2000 and 20000 K, especially 2700-20000 K, for general lighting especially in the range of about 2000-7000 K, such as in the range of 2700 K and 6500 K. In embodiments, e.g. for backlighting purposes, or for other purposes, the correlated color temperature (CCT) may especially be in the range of about 7000 K and 20000 K. Yet further, in embodiments the correlated color temperature (CCT) is especially within about 15 SDCM (standard deviation of color matching) from the BBL (black body locus), especially within about 10 SDCM from the BBL, even more especially within about 5 SDCM from the BBL.

In specific embodiments, the correlated color temperature (CCT) may be selected from the range of 6000-12000 K, like selected from the range of 7000-12000 K, like at least 8000 K. Yet further, in embodiments the correlated color temperature (CCT) may be selected from the range of 6000-12000 K, like selected from the range of 7000-12000 K, in combination with a CRI of at least 70.

In certain embodiments, the light generating system may be configured to provide system light comprising the first light source light and the second light source light. The light generating system may especially be configured such in an operational mode of the light generating system. Herein, the system light may be white light having a color rendering index of at least 60, such as at least 80, especially at least 90. Further, the system light may have a correlated color temperature selected from the range of 1600-21000 K, such as 1800-20000 K, especially 2000-10000 K.

Hence, the light generating system may comprise two stacked laser banks generating (narrow) light beams of first light source light and second light source light, together providing high intensity white system light.

The light generating system may be part of or may be applied in e.g. office lighting systems, household application systems, shop lighting systems, home lighting systems, accent lighting systems, spot lighting systems, theater lighting systems, fiber-optics application systems, projection systems, self-lit display systems, pixelated display systems, segmented display systems, warning sign systems, medical lighting application systems, indicator sign systems, decorative lighting systems, portable systems, automotive applications, (outdoor) road lighting systems, urban lighting systems, green house lighting systems, horticulture lighting, digital projection, or LCD backlighting. The light generating system (or luminaire) may be part of or may be applied in e.g. optical communication systems or disinfection systems.

In yet a further aspect, the invention also provides a lamp or a luminaire comprising the light generating system as defined herein. The luminaire may further comprise a housing, optical elements, louvres, etc. etc . . . The lamp or luminaire may further comprise a housing enclosing the light generating system. The lamp or luminaire may comprise a light window in the housing or a housing opening, through which the system light may escape from the housing. In yet a further aspect, the invention also provides a projection device comprising the light generating system as defined herein. Especially, a projection device or “projector” or “image projector” may be an optical device that projects an image (or moving images) onto a surface, such as e.g. a projection screen. The projection device may include one or more light generating systems such as described herein. Hence, in an aspect the invention also provides a lighting device selected from the group of a lamp, a luminaire, a projector device, a disinfection device, a photochemical reactor, and an optical wireless communication device, comprising the light generating system as defined herein. The lighting device may comprise a housing or a carrier, configured to house or support, one or more elements of the light generating system. For instance, in embodiments the lighting device may comprise a housing or a carrier, configured to house or support one or more of the light generating system.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1A-F schematically embodiments of the light generating system or elements thereof.

FIG. 2A-C schematically depict further embodiments of the light generating system.

FIG. 3A-B schematically depicts a top-bottom view of embodiments of the light generating system.

FIG. 4 schematically depicts some applications of the light generating system.

The schematic drawings are not necessarily to scale.

### DETAILED DESCRIPTION OF THE EMBODIMENTS

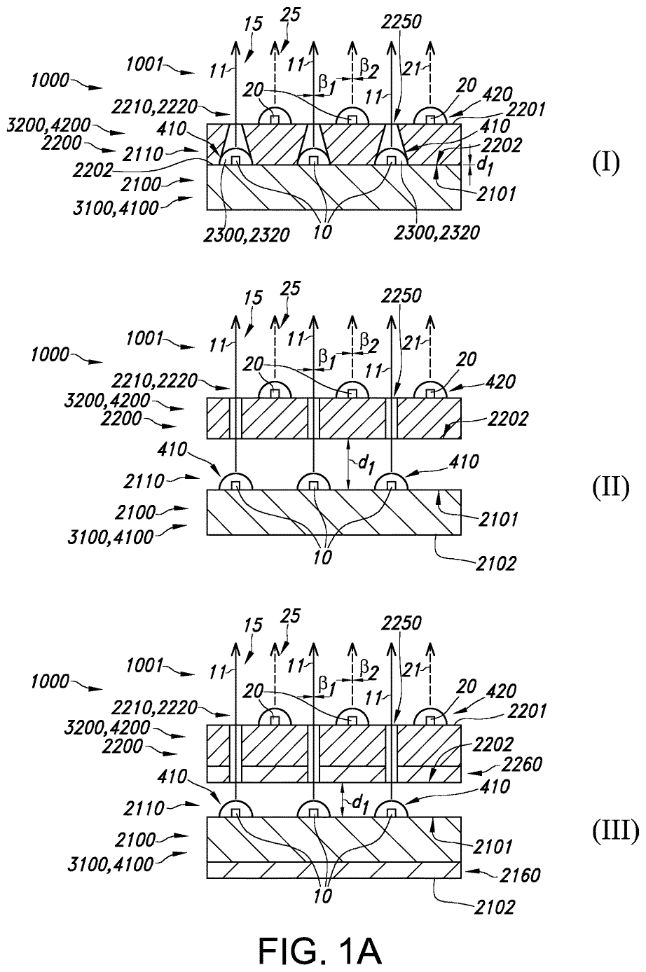

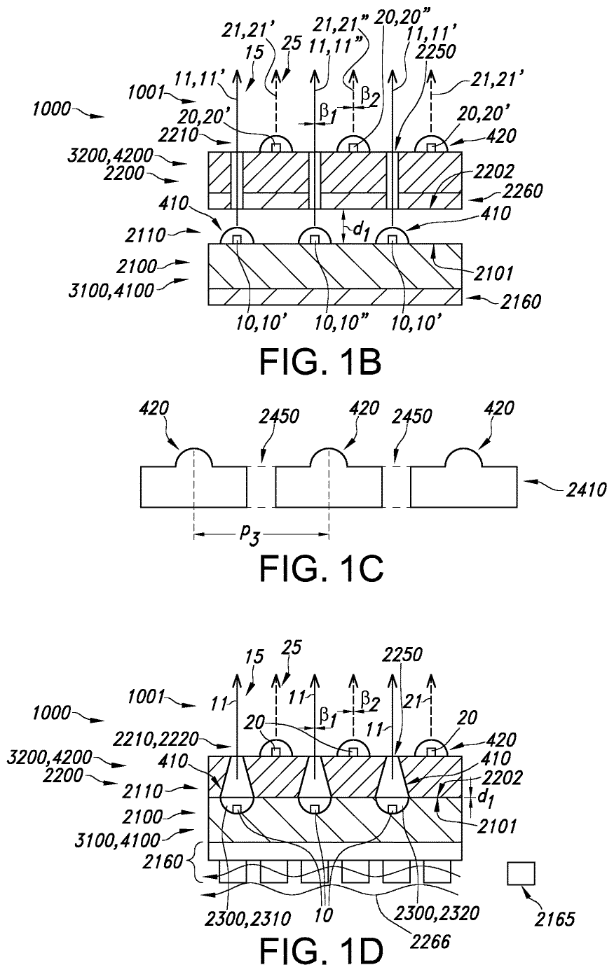

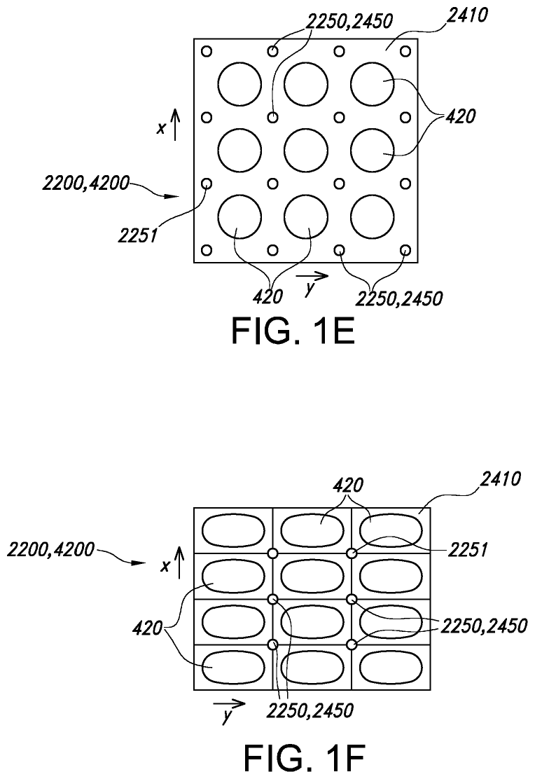

FIG. 1A-B schematically depict various embodiments of the light generating system 1000. Herein, the light generating system 1000 may in embodiments comprise a first support 2100, a first 2D array 2110 of first light sources 10, first optical elements 410, a second support 2200, a second 2D array 2210 of second light sources 20, and second optical elements 420.

Further, the first support 2100 may especially be configured to support the first light sources 10 and further the second support 2200 may be configured to support the second light sources 20. The first light sources 10 may in particular be configured to generate first light source light 11 and moreover the second light sources 20 may be configured to generate second light source light 21. Especially, the first light sources 10 may comprise laser diodes and the second light sources 20 may comprise laser diodes. Moreover, the first support 2100 may comprise a first thermally conductive element 2160 and/or the second support 2200 may comprise a second thermally conductive element 2260.

In embodiments, the first optical elements 410 may be configured downstream of the first light sources 10, and may further be configured to collimate the first light source light 11 into first beams 15 of collimated first light source light 11. Similarly, the second optical elements 420 may be configured downstream of the second light sources 20, and may moreover be configured to collimate the second light source light 21 into second beams 25 of collimated second light source light 21.

Especially, the first support 2100 and the second support 2200 may be configured stacked. The second support 2200 may comprise an array 2220 of through-holes 2250 configured aligned with the first optical elements 410. Thereby the through-holes may allow propagation of at least part of the collimated first light source light 11 through the second support 2200.

In particular, embodiments of the light generating system 1000 may be configured to generate system light 1001 comprising one or more of the first light source light 11 and the second light source light 21.

Further, in embodiments the light generating system 1000 may comprise a first laser arrangement 4100 comprising the first laser bank 3100, the first laser bank 3100 comprising: the first support 2100, the first 2D array 2110 of first light sources 10, and the first optical elements 410. The light generating system 1000 may further comprise a second laser arrangement 4200 comprising the second laser bank 3200, the second laser bank 3200 comprising: the second support 2200, the second 2D array 2210 of second light sources 20, and the second optical elements 420.

Especially, the first optical elements 410 may be configured to collimate the first light source light 11 into first beams 15 of collimated first light source light 11 having a first full width half maximum defined beam angle (β₁) of at maximum 2°. Moreover, the second optical elements 420 may be configured to collimate the second light source light 21 into second beams 25 of collimated second light source light 21 having a second full width half maximum defined beam angle (β₂) of at maximum 2°.

In embodiments, the first light source light 11 and the second light source light 21 may have a difference in centroid wavelength of at least 10 nm.

Especially, the first optical elements 410 and the second optical elements 420 may comprise aspheric lenses. Further, the one or more optical elements 410 and the second optical elements 420 may be arranged at 90 degrees.

Moreover, the light generating system 1000 may be configured to provide in an operational mode of the light generating system 1000 system light 1001 comprising the first light source light 11 and the second light source light 21. The system light 1001 may in embodiments be white light having a color rendering index of at least 80 and a correlated color temperature selected from the range of 1800-20000 K.

In specific embodiments, the first thermally conductive element 2160 and the second thermally conductive element 2260 may be individually selected from the group of a heat sink, a heat spreader, and a two-phase cooling device.

As depicted in embodiment (I) in FIG. 1A, as well as in FIG. 1D, a top side 2101 the first support 2100 and a bottom side 2202 of the second support 2200 may be configured in contact with each other, especially in physical contact with each other. Herein, the distance (d₁) may essentially be zero. Reference 2201 refers to a top side of the second support 2200.

In embodiments (II) and (III) in FIG. 1A, as well as in FIG. 1B, the top side 2101 of the first support 2100 and the bottom side 2202 of the second support 2200 may be configured at a non-zero distance (d₁) from each other.

Further, as depicted in embodiment (I) in FIG. 1A, the second support 2200 may comprise cavities 2300, especially second cavities 2320. The second cavities 2320 may be configured to host at least a subset of the first optical elements 410. Especially, the second cavities 2320 may be configured upstream of the through-holes 2250 or comprise the through-holes 2250.

Specifically, FIG. 1B depicts embodiments of the light generating system 1000 wherein the first light sources 10 may especially comprise at least two different types of first light sources 10 and the second light sources 10 may further comprise at least two different types of second light sources 20. The first light sources 10 may herein differ in one or more of (a) centroid wavelength, (b) color point and (c) correlated color temperature. The second light sources 20 may also differ in one or more of (a) centroid wavelength, (b) color point and (c) correlated color temperature. Herein, the centroid wavelength may differ at least 10 nm. Further, u′ may differs with at least 0.03 and/or v′ may differs at least 0.03. Thereby, a first type of first light sources 10′ may generate first light source light 11′ and a second type of first light sources 10″ may generate first light source light 11″, having a spectral power distribution different from the first light 11. Further, a first type of second light sources 20′ may generate second light source light 21′ and another type of second light sources 20″ may generate second light source light 21″.

FIG. 1C depicts the second optical elements 420 as comprised by a second monolithic optical body 2410 comprising optical body through-holes 2450, aligned with the through-holes 2250. Herein, the second optical elements 420 may have a second optical element pitch P₃, i.e., the distance between the center of one second optical element 420 to another second optical element 420.

FIG. 1D depicts an embodiment of the light generating system 1000 wherein the first support 2100 may comprise cavities 2300, especially first cavities 2310. The first cavities 2310 may be configured to host at least a subset of the first light sources 10. The light generating system 1000 further comprises the first thermally conductive element 2160 and an air blower fan 2165 providing an air stream 2166 to the first thermally conductive element 2160.

FIG. 1E-F schematically depict a monolithic body 2410 comprising second optical elements 420, especially lenses. The monolithic body 2410 may especially be a second monolithic body 2410 comprised by a second laser arrangement 4200. The second monolithic body 2410 may comprise optical body through-holes 2450 aligned with the through-holes 250 of the second support 2200. The through-holes 2250 may have hole axes 2251.

FIG. 1E specifically depicts embodiments wherein the second optical elements 420 comprise circular lenses, though other shapes may also be possible. The packing density of lasers in Y direction is equal to the packing density of light sources in X direction.

FIG. 1F specifically depicts embodiments wherein the second optical elements 420 comprise aspherical lenses. The packing density of lasers in Y direction is lower than the packing density of light sources in X direction.

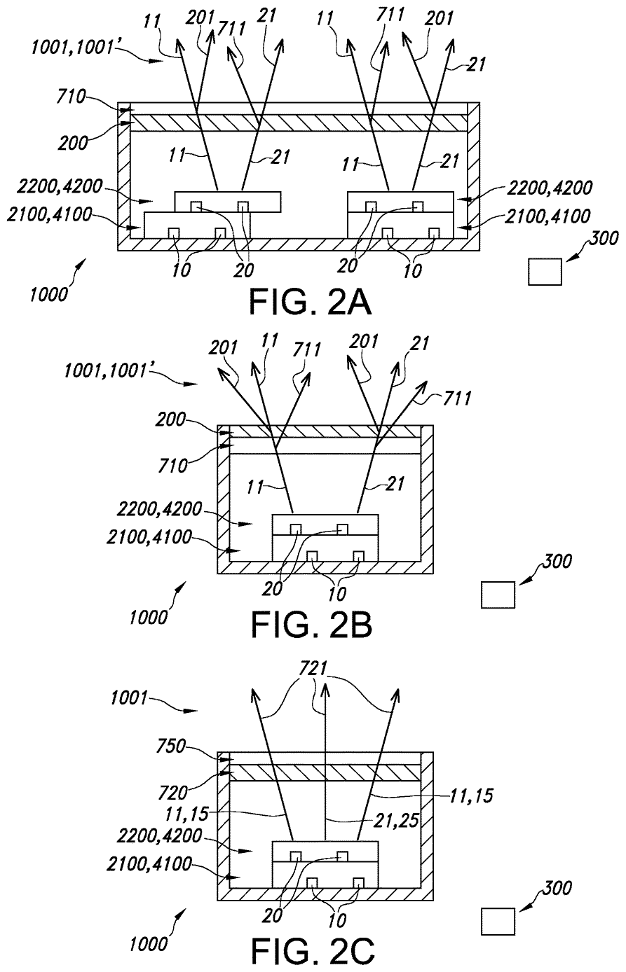

FIG. 2A-B schematically depict a light generating system 1000 further comprising (a) a diffuser element 710 and (b) a luminescent material 200. The diffuser element 710 may especially be configured downstream of the first light sources 10 and the second light sources 20. The diffuser element 710 may further be configured to diffuse at least part of the first light source light 11 and/or at least of the second light source light 21 into diffused light 711. The luminescent material 200 may additionally be configured downstream of the first light sources 10 and the second light sources 20. The luminescent material 200 may further be configured to convert at least part of the first light source light 11 and/or at least of the second light source light 21 into luminescent material light. Herein, the light generating system 1000 may be configured to provide in an operational mode of the light generating system 1000 system light 1001 comprising the luminescent material light 201 and the diffused light 711. The system light 1001 may especially be white light having a color rendering index of at least 80 and a correlated color temperature selected from the range of 1800-10000 K.

In particular, FIG. 2A depicts an embodiment of the light generating system 1000 comprising a luminescent material 200 configured downstream of the light sources 10,20. The depicted light generating system 1000 further comprises a diffuser element 710 configured downstream of the luminescent material 200. The system light 1001 comprising the first light source light 11 and/or second light source light 21 may at least partly be configured into system light at least comprising luminescent material light 201. The latter (converted) system light is indicated with reference 1001′.

FIG. 2B however depicts an embodiment of the light generating system 1000 comprising a diffuser element 710 configured downstream of the light sources 10,20. The depicted light generating system 1000 further comprises a luminescent material 200 configured downstream of the diffuser element 710.

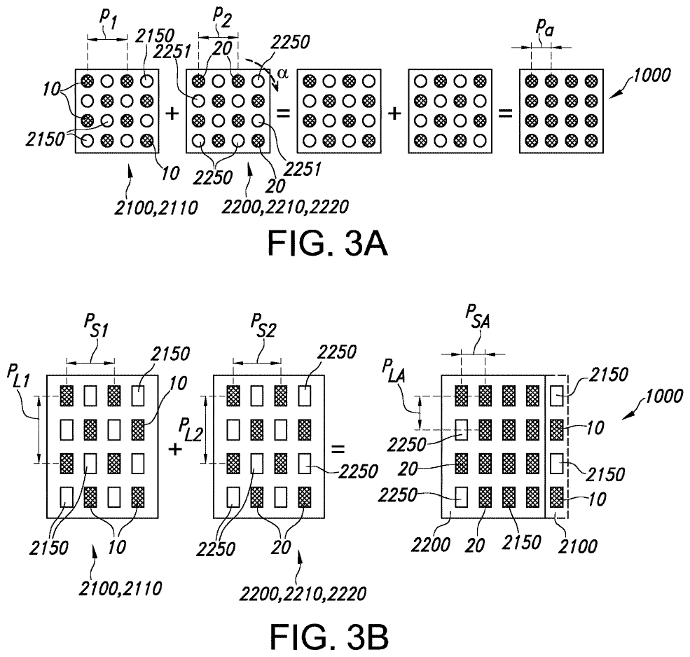

Especially, FIG. 2A depicts an embodiment comprising two configurations of the first laser arrangement 4100 and the second laser arrangement 4200. In one configuration, the first laser arrangement 4100 and the second laser arrangement 4200 are stacked aligned to each other. In another configuration, the first laser arrangement 4100 and the second laser arrangement 4200 are stacked partially overlapping with each other; see e.g. also FIGS. 3a-3b.

Further FIG. 2C depicts a light generating system 1000 comprising a homogenizer element 720. The homogenizer element 720 may be configured to homogenize the first beams 15 of collimated first light source light 11 and the second beams 25 of collimated second light source light 21. The homogenizer element 720 may therefore be configured downstream of the light sources 10,20. The light generating system 1000 may further comprise a system light window 750 arranged downstream of the homogenizer element 720. Hence, the light generating system 1000 may be configured to provide in an operational mode of the light generating system 1000 system light 1001, especially homogenized system light 721, comprising the first light source light 11 and the second light source light 21.

FIG. 3A-B depicts a top-bottom view of light generating system 1000. Herein, the through-holes 2250 may have hole axes 2251. Further, the through-holes 2250 may have largest circular equivalent diameters D_{C1} defined perpendicular to the hole axes 2251 of at maximum 5 mm. In particular, the largest circular equivalent diameters D_{C1} may be selected from the range of 0.5-3 mm.

As depicted in FIG. 3A, the through-holes 2250 may have a cylindrical shape, especially an elongated cylindrical shape. Especially, the first 2D array 2110 may have a first array pitch P₁. Similarly, the second 2D array 2210 may have a second array pitch P₂. The first array pitch P₁ and the second array pitch P₂ may especially have a mutual angle α of 90°. Thereby, the light generating system 1000 may have an overall pitch P_{A} of light sources (10,20). Hence, P_{A}=0.5*P₁. Further, P_{A}=0.5*P₂.

Depicted in FIG. 3B, the through-holes 2250 may have a rectangular shape, especially a shape fitting laser bars. Further, the first 2D array 2110 may have a longest first array pitch P_{L1} and a shortest first array pitch P_{S1}. Similarly, the second 2D array 2210 may have a longest second array pitch P_{L2} and a shortest second array pitch P_{S2}. Thereby, the light generating system 1000 may have an overall longest pitch P_{LA} and overall shortest pitch P_{LA} of light sources 10,20.

In alternative embodiments, the first support 2100 and second support 2200 may be rotated, see also FIG. 3a.

In yet other embodiments, two different types of first support 2100 and second support 2200, wherein at the hole positions and light source positions are interchanged. Also in this way a small pitch and thus high intensity light generating system may be applied.

Dependent upon the choice, the supports 2100,2200 may be stacked, and configured essentially on top of each other, like in FIG. 3a, and in FIG. 2a on the right, or may be stacked and shifted, like in FIG. 3b and FIG. 2a on the left.

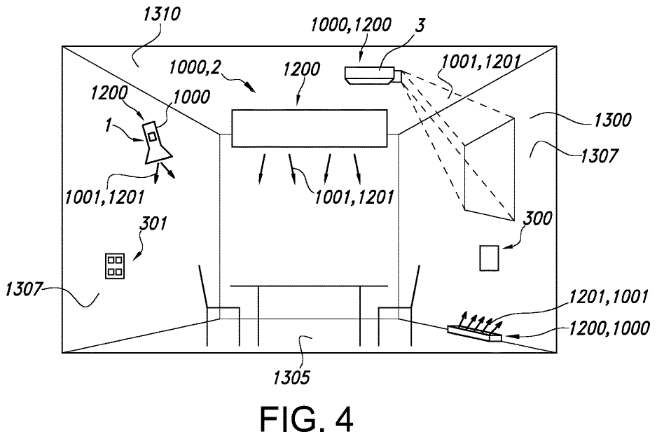

FIG. 4 schematically depicts an embodiment of a luminaire 2 comprising the light generating system 1000 as described above. Reference 301 indicates a user interface which may be functionally coupled with the control system 300 comprised by or functionally coupled to the light generating system 1000. FIG. 4 also schematically depicts an embodiment of lamp 1 comprising the light generating system 1000. Reference 3 indicates a projector device or projector system, which may be used to project images, such as at a wall, which may also comprise the light generating system 1000. Hence, FIG. 3 schematically depicts embodiments of a lighting device 1200 selected from the group of a lamp 1, a luminaire 2, a projector device 3, a disinfection device, a photochemical reactor, and an optical wireless communication device, comprising the light generating system 1000 as described herein. In embodiments, such lighting device may be a lamp 1, a luminaire 2, a projector device 3, a disinfection device, an optical wireless communication device, or an automotive lighting device. Lighting device light escaping from the lighting device 1200 is indicated with reference 1201. Lighting device light 1201 may essentially consist of system light 1001, and may in specific embodiments thus be system light 1001. Reference 1300 refers to a space, such as a room. Reference 1305 refers to a floor and reference 1310 to a ceiling; reference 1307 refers to a wall.

The term “plurality” refers to two or more.

The terms “substantially” or “essentially” herein, and similar terms, will be understood by the person skilled in the art. The terms “substantially” or “essentially” may also include embodiments with “entirely”, “completely”, “all”, etc. Hence, in embodiments the adjective substantially or essentially may also be removed. Where applicable, the term “substantially” or the term “essentially” may also relate to 90% or higher, such as 95% or higher, especially 99% or higher, even more especially 99.5% or higher, including 100%.

The term “comprise” also includes embodiments wherein the term “comprises” means “consists of”.

The term “and/or” especially relates to one or more of the items mentioned before and after “and/or”. For instance, a phrase “item 1 and/or item 2” and similar phrases may relate to one or more of item 1 and item 2. The term “comprising” may in an embodiment refer to “consisting of” but may in another embodiment also refer to “containing at least the defined species and optionally one or more other species”.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The devices, apparatus, or systems may herein amongst others be described during operation. As will be clear to the person skilled in the art, the invention is not limited to methods of operation, or devices, apparatus, or systems in operation.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim.

Use of the verb “to comprise” and its conjugations does not exclude the presence of elements or steps other than those stated in a claim. Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”.

The article “a” or “an” preceding an element does not exclude the presence of a plurality of such elements.

The invention may be implemented by means of hardware comprising several distinct elements, and by means of a suitably programmed computer. In a device claim, or an apparatus claim, or a system claim, enumerating several means, several of these means may be embodied by one and the same item of hardware. The mere fact that certain measures are recited in mutually different dependent claims does not indicate that a combination of these measures cannot be used to advantage. In yet a further aspect, the invention (thus) provides a software product, which, when running on a computer is capable of bringing about (one or more embodiments of) the method as described herein.

The invention also provides a control system that may control the device, apparatus, or system, or that may execute the herein described method or process. Yet further, the invention also provides a computer program product, when running on a computer which is functionally coupled to or comprised by the device, apparatus, or system, controls one or more controllable elements of such device, apparatus, or system.

The invention further applies to a device, apparatus, or system comprising one or more of the characterizing features described in the description and/or shown in the attached drawings. The invention further pertains to a method or process comprising one or more of the characterizing features described in the description and/or shown in the attached drawings.

The various aspects discussed in this patent can be combined in order to provide additional advantages. Further, the person skilled in the art will understand that embodiments can be combined, and that also more than two embodiments can be combined. Furthermore, some of the features can form the basis for one or more divisional applications.

1. A light generating system comprising a first support, a first 2D array of first light sources, first optical elements, a second support, a second 2D array of second light sources, and second optical elements, wherein:
the first support is configured to support the first light sources and the second support is configured to support the second light sources; the first light sources are configured to generate first light source light and the second light sources are configured to generate second light source light; wherein the first light sources comprise laser diodes and the second light sources comprise laser diodes; wherein the first support comprises a first thermally conductive element and/or wherein the second support comprises a second thermally conductive element;
the first optical elements are configured downstream of the first light sources, and are configured to collimate the first light source light into first beams of collimated first light source light; the second optical elements are configured downstream of the second light sources, and are configured to collimate the second light source light into second beams of collimated second light source light;
the first support and the second support are configured stacked, wherein the second support comprises an array of through-holes configured aligned with the first optical elements to allow propagation of at least part of the collimated first light source light through the second support;
a first laser bank comprises the first support, the first 2D array of first light sources, and the first optical elements, and/or a second laser bank comprises the second support, the second 2D array of second light sources, and the second optical elements;
the first optical elements are configured to collimate the first light source light into first beams of collimated first light source light having a first full width half maximum defined beam angle of at maximum 2°, and/or the second optical elements are configured to collimate the second light source light into second beams of collimated second light source light having a second full width half maximum defined beam angle of at maximum 2°; and
the light generating system is configured to generate system light comprising one or more of the first light source light and the second light source light.

2. The light generating system according to claim 1, wherein the second support comprises second cavities, wherein the second cavities are configured to host at least a subset of the first optical elements.

3. The light generating system according to claim 1, wherein a top side of the first the first support and a bottom side of the second support are configured in contact with each other, or wherein the top side of the first support and the bottom side of the second support are configured at a non-zero distance from each other.

4. The light generating system according to claim 1, wherein the through-holes have hole axes, wherein the through-holes have largest circular equivalent diameters D_{C1} defined perpendicular to the hole axes of at maximum 5 mm.

5. The light generating system according to claim 1, wherein the through-holes have a cylindrical shape.

6. The light generating system according to claim 1, wherein the second optical elements are comprised by a monolithic optical body comprising optical body through-holes, aligned with the through-holes; wherein the first thermally conductive element and the second thermally conductive element are individually selected from the group of a heat sink, a heat spreader, and a two-phase cooling device.

7. The light generating system according to claim 1, wherein the first 2D array has a first array pitch, wherein the second 2D array has a second array pitch, wherein one or more of the following applies: (a) the first array pitch and the second array pitch have a mutual angle of 90°, and (b) the light generating system has an overall pitch of light sources, wherein Pa=0.5*P1.

8. The light generating system according to claim 1, wherein the first light source light and the second light source light have a difference in centroid wavelength of at least 10 nm.

9. The light generating system according to claim 1, wherein the first optical elements and the second optical elements comprise aspheric lenses.

10. The light generating system according to claim 6, wherein the second optical elements comprise rectangular-like shaped lenses, wherein the through-holes are configured at positions between subsets of three or four second optical elements; wherein the monolithic optical body comprises the rectangular-like shaped lenses.

11. The light generating system according to claim 1, wherein:
the first light sources comprise at least two different types of first light sources, differing in one or more of (a) centroid wavelength, wherein the centroid wavelength differs at least 10 nm, and (b) color point, wherein u′ differs with at least 0.03 and/or wherein v′ differs at least 0.03, and/or
the second light sources comprise at least two different types of second light sources, differing in one or more of (a) centroid wavelength, wherein the centroid wavelength differs at least 10 nm, and (b) color point, wherein u′ differs with at least 0.03 and/or wherein v′ differs at least 0.03.

12. The light generating system according to claim 1, wherein the first laser bank comprises the first 2D array and a shared first support, a shared first heat sinking, and shared first optical elements, and/or wherein the second laser bank comprises the second 2D array and a shared second support, a shared second heat sinking, and shared second optical elements.

13. The light generating system, according to claim 1, wherein: the light generating system comprises a homogenizer element configured to homogenize the first beams, of collimated first light source light and the second beams of collimated second light source light; the light generating system further comprises a system light window arranged downstream of the homogenizer element; and the light generating system is configured to provide in an operational mode of the light generating system homogenized system light comprising the first light source light and the second light source light.

14. The light generating system according to claim 1, further comprising (a) a diffuser element and (b) a luminescent material, wherein: (a) the diffuser element is configured downstream of the first light sources and the second light sources, and the diffuser element is configured to diffuse at least part of the first light source light and/or at least of the second light source light into diffused light, and (b) the luminescent material is configured downstream of the first light sources and the second light sources, and the luminescent material is configured to convert at least part of the first light source light and/or at least of the second light source light into luminescent material light; wherein the light generating system is configured to provide in an operational mode of the light generating system system light comprising the luminescent material light and the diffused light, wherein the system light is white light having a color rendering index of at least 80 and a correlated color temperature selected from the range of 1800-10000 K.

15. A lighting device selected from the group of a lamp, a luminaire, a projector device, a disinfection device, a photochemical reactor, an automotive lighting device, and an optical wireless communication device, comprising the light generating system according to claim 1.
